(19) United States
(12) Patent Application Publication
(10) Pub. No.: US 2008/0134759 A1
(43) Pub. Date: Jun. 12, 2008

(54) Sensor for Detection and/or Measuring a Concentration of Electrical Charges Contained in an Environment, Corresponding Uses and Method of Manufacture Thereof

(75) Inventors: Tayeb Mohammed-Brahim, Rennes (FR); Anne-Claire Saluan, Rennes (FR); France Le Bihan, Cesson-Sevigne (FR); Hichan Kotb, Rennes (FR); Farida Bendriaa, Cesson-Sevigne (FR); Olivier Bonnaud, Cesson-Bonnaud (FR)

Correspondence Address: WESTMAN CHAMPLIN & KELLY, P.A., SUITE 1400, 900 SECOND AVENUE SOUTH, MINNEAPOLIS, MN, 55402-3319, US

(73) Assignee: UNIVERSITE DE RENNES 1, RENNES CEDEX 7 (FR)

(21) Appl. No.: 11/631,839

(22) PCT Filed: Jul. 7, 2005
(86) PCT No.: PCT/FR05/01761

§ 371 Date: Dec. 31, 2007

(30) Foreign Application Priority Data
Jul. 7, 2004 (FR) 04/07583

(51) Int. Cl. G01N 27/414; H01L 29/772

(52) U.S. Cl. 73/31.06; 257/253; 324/76.11; 73/53.01; 257/E29.242

(57) ABSTRACT

The invention concerns a sensor for detecting and/or measuring concentration of electric charges contained in an atmosphere. The sensor comprises a field-effect transistor structure including a bridge, which forms a gate and is suspended above an active layer located between drain and source regions. A gate voltage having a specific value is applied on the bridge. A so-called air gap region is included between the bridge and the active layer or an insulating layer deposited on said active layer, and has a specific height. An electric field (E), defined as the ratio between the gate voltage and air gap height, is generated in the air gap. The electric field generated in the air gap has a value not less than a specific threshold, sufficiently important for the electric field (E) to influence the distribution of electric charges contained in the atmosphere and present in the air gap, and to enable high sensitivity of the sensor to be achieved through accumulation of the electric charges on the active layer.

### CROSS-REFERENCE TO RELATED APPLICATION

This Application is a Section 371 National Stage Application of International Application No. PCT/FR2005/001761, filed Jul. 7, 2005 and published as WO 2006/013289 on Feb. 9, 2006, not in English.

### FIELD OF THE DISCLOSURE

The field of the disclosure is that of chemical and biological sensors capable of being used in gaseous or liquid environments.

More precisely, the disclosure relates to a highly sensitive sensor for detecting and/or measuring a concentration of electrical charges present in a gaseous or liquid environment.

The sensor of an embodiment of the invention belongs to the category of sensors comprising a field-effect transistor structure including a bridge that forms the gate and is suspended above an active layer situated between drain and source regions.

An embodiment of the invention has numerous applications, e.g., such as sensors sensitive to NH₃, NO₂, humidity, or smoke, in gaseous environments, or else sensors sensitive to the pH of solutions, in liquid environments.

More generally, it can be applied in any gas or liquid environment containing electrical charges. However, it is important to note that this invention does not apply to electrically neutral environments.

### BACKGROUND

The history of the chemically sensitive field-effect transistor (or FET) began 30 years ago. It includes gas-sensitive structures in gaseous environments, as well as ion-sensitive structures in liquid environments.

Conventionally, a gas-sensitive field-effect transistor (FET structure) is produced by using:
either a permeable gate, made of palladium or polymers, which is placed against the active layer situated between the drain and source regions, whereby the gas reaches the active layer by passing through openings passing through the permeable gate;
or a suspended gate (also called a “suspended bridge”), which allows the presence of gas in the so-called “air-gap” region contained between the gate and the active layer situated between the drain and source regions, or between the gate and an insulating layer deposited on the active layer.

The suspended gate FET structure was described by J. Janata in the U.S. Pat. Nos. 4,411,741 (1983) and 4,514,263 (1985). This structure uses a conventional P-type single-crystal silicon FET transistor with a suspended and perforated gate forming a bridge. The sensitive parameter is the work function of the bridge, which varies in relation to the adsorption of dipoles contained in the fluid, likewise requiring a variation of the flat-band voltage of the structure.

Another patent [S. C. Pyke, U.S. Pat. No. 4,671,852 (1987)] discloses a method for forming a suspended gate, chemically sensitive FET based on the removal of a sacrificial layer. As for the preceding patent, a metal gate is used for the suspended bridge.

B. Flietner, T. Doll, J. Lechner, M. Leu and I. Eisele (Sensors and Actuators B, 18-19 (1994) pp. 632-636) proposed a hybrid suspended gate FET (HSGFET) making it possible to easily deposit sensitive layers between the gate and the channel of the transistor (i.e., between the gate and the active layer of the transistor). In this method, the gate is formed separately and is then fastened onto the previously formed gateless FET.

Subsequent to these patents, a significant number of publications and patents were produced for the purpose of optimising the gas-sensitive suspended gate FET structure. These works mainly dealt with optimisation of the materials used to produce the sensitive layer on which the adsorption phenomenon occurs.

The gas sensitivity of these known FET structures is explained by the variation of the work function of the sensitive layer under exposure to gases, which produces a shift of the threshold voltage. In other words, the sensitive parameter is the work function, which varies in relation to the adsorption, by the sensitive layer, of molecules (e.g., dipoles) contained in the (so-called air-gap) region contained between the bridge and the active layer (and more precisely, in this case where there is adsorption, between the bridge and the sensitive layer).

It is recalled that, conventionally, in order to obtain an indication of the quantity of desired molecules present in the air gap, the current between the drain and source regions is measured (the current I_{DS} that passes into the active layer) and it is determined how the measured current varies. Using the current-day technique described above, which is based on the adsorption phenomenon, the variation of the measured current results from the adsorption of molecules by the sensitive layer. For example, as explained in the aforesaid U.S. Pat. No. 4,514,263, in the case where a positive charge is present on the bridge, the larger the quantity of dipoles adsorbed by a sensitive layer deposited on the active layer, the stronger the current I_{DS}. As a matter of fact, in this case, the adsorbed dipoles align themselves, the positive end of each of the adsorbed dipoles being oriented towards the active layer, which leads to an increase in the number of electrons attracted and thus to an increase in the current I_{DS} that passes into the active layer.

The ion-sensitive structure in a liquid environment (or solution) is called Bergveld's Ion-Sensitive FET (ISFET). This is a gateless structure comprising, on the one hand, a sensitive layer, which covers the channel insulator, and, on the other hand, a reference electrode dipped into the solution and fixing the gate bias.

Although the first publication about this structure is by P. Bergveld [“Development of an ion-sensitive solid-state device for neuro-physiological measurements”, IEEE Trans. Biomed. Eng. 17 (1970) pp. 70-71], the first patent belongs to C. C. Johnson, S. D. Moss, J. A. Janata, “Selective chemical sensitive FET transducers”, U.S. Pat. No. 4,020,830 (1977).

Since this patent, more than 500 publications and 150 patents have been devoted to the ISFETs. The primary subjects addressed relate to improving the sensitivity and selectivity of the sensitive layer on which the adsorption phenomenon occurs, (U.S. Pat. Nos. 5,319,226/5,350,701/5,387,328), the study of drift as well as the effect of temperature and the use of a reference FET structure (J. M. Chovelon, Sensors and Actuators B8 (1992) pp. 221-225).

As for the gas-sensitive FET structures, the sensitivity of the ISFETs is explained by the variation in the threshold voltage induced by the variation in the flat-band voltage V_{FB}. In other words, only the effect of the adsorption phenomenon is used in known ISFETs.

$${V}_{FB} is expressed by \text{:} {V}_{FB} = {V}_{ref} - {Ψ}_{0} - {χ}^{sol} - \frac{{Φ}_{s}}{q}$$

where V_{ref} is the contribution of the reference electrode, χ^{sol} the surface dipole potential of the solution, Ψ₀ the surface potential at the interface between the insulator and the solution, Φₛ the semiconductor work function.

Only Ψ₀ is sensitive to the pH value. The relationship Ψ₀—pH is given by (R. E. G. van Hal, J. C. T. Eijkel, P. Berveld, “A general model to describe the electrostatic potential at electrolyte/oxide interfaces”, Adv. Colloid. Interface Sci. 69 (1966) pp. 31-62):

$$\frac{\partial {Ψ}_{0}}{\partial {pH}_{Bulk}} = - 2.3 \frac{kT}{q} α$$

where α is a dimensionless parameter, ranging between 0 and 1. When a is equal to 1, the maximum sensitivity of 59 mV/pH is reached, also called the Nernstian sensitivity.

No previous patent or published work has reported higher sensitivity without using an amplifying circuit.

One disadvantage of known sensors comprising a field-effect transistor structure is that they have limited sensitivity. Typically, this sensitivity is limited to 59 mV/pH, in the case of a liquid environment.

### SUMMARY

An embodiment is directed to a sensor for detecting and/or measuring a concentration of electrical charges contained in an environment, said sensor comprising a field-effect transistor structure including a bridge which forms a gate and is suspended above an active layer situated between the drain and source regions. A gate voltage having a specific value is applied to the bridge. A so-called air-gap region is included between the bridge and the active layer or an insulating layer deposited on said active layer, and has a specific height. An electric field E, defined as the ratio between the gate voltage and the air gap height, is generated in the air gap. According to an embodiment of the invention, the electric field E generated in the air gap has a value greater than or equal to a specific threshold value, which is sufficiently large for the electric field E to influence the distribution of electrical charges contained in the environment and present in the air gap, and to enable high sensor sensitivity to be obtained by an accumulation of electrical charges on the active layer. The surface of the bridge is covered with an insulating material.

The basic principle of an embodiment of the invention, whether the latter is applied in a gaseous or liquid environment, consists in creating a strong electric field in the air gap, making it possible to push the electrical charges towards the active layer as well as to improve the sensitivity of the sensor. Therefore, an embodiment of this invention does not apply to electrically neutral environments in which there are no electrical charges on which the electric field created in the air gap is able to act.

It is important to note that an embodiment of this invention rests on the effect produced by a new distribution of the charges in the air gap owing to the application of a strong electric field, and not on the adsorption phenomenon. In known sensors based on the adsorption phenomenon, the effect on which an embodiment of this invention rests does not exist because the electric field applied in the air gap is much too weak. As a matter of fact, the inventors take the position that the effect on which an embodiment of this invention rests exists only if the electric field applied in the air gap is a strong field, greater than or equal to 50,000 V/cm. Such being the case, the electric field applied in the air gap in known sensors is a weak field, generally much lower than 1,000 V/cm.

It shall also be noted that the presumptions of those skilled in the art have always led to the belief that it was not necessary to increase the value of the electric field created in the air gap too much, so as to not saturate the adsorption by the surfaces of the air gap.

Two implementations of the sensor of an embodiment of the invention are thus possible:
in a first implementation, the sensor uses only the effect characteristic of the embodiment of the invention (new distribution of the charges in the air gap owing to the application of a strong electric field), and thus does not use the adsorption phenomenon. In this case, no sensitive layer is necessary and the embodiment of the invention thus makes it possible to lift the constraint in the choice of the material used for the sensitive layer (on which the adsorption phenomenon occurs); and
in a second implementation, the sensor combines the effect characteristic of an embodiment of the invention (new distribution of the charges in the air gap owing to the application of a strong electric field) and the adsorption effect. In this case, a sensitive layer is necessary for adsorption.

An embodiment of invention relates to any geometry wherein the field effect, due the voltage applied on the suspended bridge, is high enough to influence the distribution of electrical charges present in the environment. It is recalled that the modulation of the current between the drain and source regions is primarily due to the variation in the distribution of the charges present in the air gap, between the bridge and the active layer (or between the bridge and an insulating layer deposited on the active layer).

Preferentially, the electric field created in the air gap has a value greater than or equal to 100,000 V/cm.

Even more preferentially, the electric field created in the air gap has a value greater than or equal to 200,000 V/cm.

Advantageously, the height of the air gap is less than 1 μm.

Preferentially, the height of the air gap is less than 0.5 μm.

It is understood that, by reducing the height of the air gap, it is possible to apply a stronger electric field without increasing the gate voltage V_{GS} applied to the bridge, or else to apply the same electric field with a weaker gate voltage V_{GS}.

In one particular embodiment of the invention, at least one portion of the structure, including the drain and source regions, and the active layer, is covered with an insulating material, so that the sensor can be dipped into a liquid environment.

In this embodiment specific to a liquid environment, the sensor according to the invention differs from the known ISFET structure (see above discussion) in that the gate (suspended bridge) serves as the reference electrode and in that the height of the air gap and the gate voltage applied to the bridge are appropriately selected so that a strong electric filed exists in this air gap, thereby making it possible to push the electrical charges towards the active layer.

An embodiment of invention also relates to a use of the aforesaid sensor (according to an embodiment of the invention) for detecting and/or measuring a concentration of electrical charges contained in an environment.

The environment containing electrical charges advantageously belongs to the group including gaseous environments and liquid environments.

In a first advantageous use of the sensor according to an embodiment of the invention, the electrical charges are NH₃ molecules contained in a gaseous environment.

In a second advantageous use of the sensor according to an embodiment of the invention, the electrical charges are NO₂ molecules contained in a gaseous environment.

It shall be noted that the NH₃ and NO₂ molecules are dipolar molecules and, on these grounds, can be qualified as electrical charges, within the meaning of an embodiment of this invention. As a matter of fact, the electric field created in the air gap influences the movement of the dipolar molecules present in this air gap (even if these dipolar molecules are electrically neutral overall).

In a third advantageous use of the sensor according to an embodiment of the invention, the electrical charges are H⁺ ions contained in a liquid environment.

In a fourth advantageous use, the sensor according to an embodiment of the invention is used for detecting and/or measuring the humidity ratio in a gaseous environment, by detecting and/or measuring a concentration of OH⁻ ions contained in said gaseous environment.

In a fifth advantageous use, the sensor according to an embodiment of the invention is used for detecting and/or measuring a concentration of smoke in a gaseous environment, by detecting and/or measuring electrical charges contained in said smoke and contained in said gaseous environment.

In a sixth advantageous use, the sensor according to an embodiment of the invention is used for measuring air quality, by measuring the quantity of negative electrical charges contained in the air.

In a seventh advantageous use, the sensor according to an embodiment of the invention is used for detecting and/or measuring a void fraction in a gaseous environment, by detecting and/or measuring electrical charges that have not been eliminated from said gaseous environment.

As a matter of fact, when the void is established, the air, and thus the charges contained in the environment, are eliminated.

In an eighth advantageous use, the sensor according to an embodiment of the invention is used for measuring the pH of a liquid environment, by measuring a concentration of H⁺ ions contained in said liquid environment.

The pH sensitivity depends on the field effect via the thickness of the air gap. It decreases when the thickness of the air gap increases.

In a ninth advantageous use, the sensor according to an embodiment of the invention is used for detecting electrically charged biological entities contained in said environment.

The term biological entities is understood to mean, in particular but not exclusively, DNA cells or branches.

It is clear that numerous other applications can be anticipated without exceeding the scope of the invention.

An embodiment of invention also relates to a method for manufacturing a sensor such as the aforesaid one (according to an embodiment of the invention). In this method, the suspended bridge, field-effect transistor structure is produced using a surface micro-technology technique.

The advantage in using the surface micro-technology technique is that it makes it possible to easily obtain an air gap having a small height, as recommended by an embodiment of this invention (a height advantageously less than or equal to 0.5 μm, and preferentially less than or equal to 1 μm).

### BRIEF DESCRIPTION OF THE DRAWINGS

Other characteristics and advantages will become apparent upon reading the following description of a preferred embodiment of the invention, given for non-limiting and illustrative purposes, and from the appended drawings.

FIGS. 1a and 1b each show a schematic view, as a sectional view and perspective view, respectively, of a first particular embodiment of a sensor, suitable for use in a gaseous environment;

FIG. 1c is an electron-microscopic view of a sensor, of the type shown schematically in FIGS. 1a and 1b;

FIG. 1d is a zoomed-in view of a portion of FIG. 1c, showing the air gap in particular;

FIG. 2a shows two transfer characteristics (drain-source current I_{DS}—gate voltage V_{GS}) of the same particular embodiment of a sensor, one being obtained when the sensor is placed in dry air, the other after 100 ppm of NH₃ have been introduced into the environment;

FIG. 2b shows two transfer characteristics (drain-source current I_{DS}—gate voltage V_{GS}) of the same particular embodiment of a sensor, placed in air having a relative humidity ratio of 10%, obtained before and after the introduction of 2 ppm of NO₂, respectively;

FIG. 2c shows a plurality of transfer characteristics (drain-source current I_{DS}—gate voltage V_{GS}) of the same particular embodiment of a sensor, obtained at various successive moments after the introduction of smoke into the environment;

FIG. 2d completes FIG. 2c by showing a variation curve for the threshold voltage in relation to the time elapsed since introduction of the smoke;

FIG. 2e shows a linear plotting (and not in a logarithmic scale as in the other figures) of a plurality of transfer characteristics (drain-source current I_{DS}—gate voltage V_{GS}) of the same particular embodiment of a sensor, obtained at various successive moments after the introduction of smoke into the environment;

FIG. 2f shows a plurality of transfer characteristics (drain-source current I_{DS}—gate voltage V_{GS}) of the same particular embodiment of a sensor, obtained for various relative degrees of humidity in the environment;

FIG. 2g completes FIG. 2f by showing a variation curve for the threshold voltage in relation to the humidity ratio;

FIG. 2h shows a plurality of transfer characteristics (drain-source current I_{DS}—gate voltage V_{GS}) for the same particular embodiment of a sensor, obtained at 10% and 20% relative humidity and before and after the introduction of smoke into the environment;

FIG. 3 shows a cross-sectional schematic view of a second particular embodiment of a sensor, suitable for use in a liquid environment;

FIG. 4a shows a variation curve for the gate voltage in relation to the pH, for a drain-source current of 100 μA and for an air gap thickness of 0.5 μm; and

FIG. 4b shows a variation curve for the gate voltage in relation to the pH, for a drain-source current of 400 μA and for an air gap thickness of 0.8 μm; and

FIG. 5 shows a plurality of transfer characteristics (drain-source current I_{DS}—gate voltage V_{GS}) for the same particular embodiment of a sensor, obtained after the sensor was dipped into various liquid environments: deionised water, KOH solution, KCl solution and NACl solution.

### DETAILED DESCRIPTION OF ILLUSTRATIVE EMBODIMENTS

This disclosure relates to a highly sensitive sensor for detecting and measuring the concentration of electrical charges contained in an environment. The sensitivity amplification effect is due to a field effect introduced via a bridge suspended above (a small height) a resistive region (active layer) contained between drain and source regions. The modulation of the current measured between the drain and source regions (“drain-source current” I_{DS}) is due in large part to the modification of the distribution of the charges present in the air gap, between the bridge and the active layer (or between the bridge and an insulating layer deposited on the active layer).

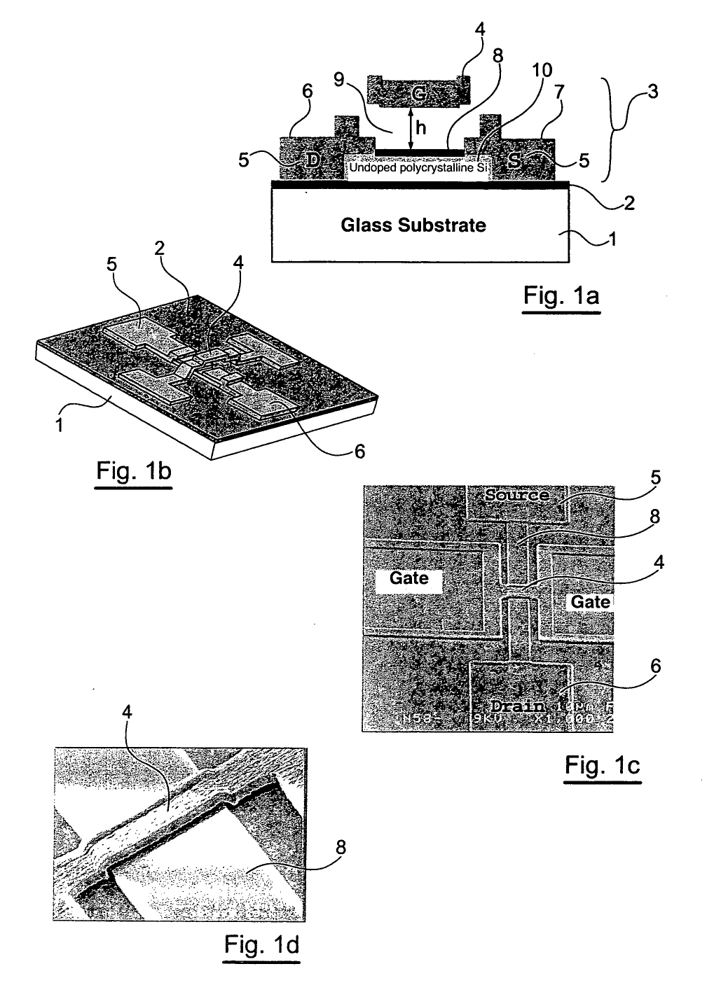

A first particular embodiment of a sensor, suitable for use in a gaseous environment, will now be presented in relation to FIGS. 1a, 1b, 1c and 1d.

In this first embodiment, the sensor includes a typical field-effect transistor structure 3, deposited on a glass substrate covered with a silicon nitride film 2.

The field-effect transistor structure 3 includes a suspended bridge 4 serving as a gate (G), made of highly doped polycrystalline silicon.

In this example, the field-effect transistor is actually a thin-film transistor (TFT). The polycrystalline silicon bridge is produced by using surface micro-technology techniques. The structure thus made using the surface micro-technology techniques is, for example, called a “Suspended Gate Thin-Film Transistor” (SGTFT).

However, it is clear that an embodiment of the invention relates to all field-effect transistor structures for which the electric field is sufficiently strong to influence the distribution of the electrical charges present in the environment.

The field-effect transistor structure 3 includes an unintentionally doped polycrystalline silicon film (active layer) 10, deposited on the glass substrate 1 covered with the silicon nitride layer 2. Any other insulating substrate or substrate covered with any electrical insulation can also be used. The polycrystalline silicon layer, for example, is deposited amorphously and is then crystallised. It can also be deposited directly in the crystallised state. Any other undoped or lightly doped semiconductor can also be used.

A second polycrystalline silicon layer 5, which is this time highly in-situ doped, is then deposited and etched to form the source (S)7 and drain (D)6 regions. It can also be deposited amorphously and then crystallised or deposited directly in the crystallised state. It can also be post-doped by any doping method. Any other highly conductive material can also be used.

Optionally, a silicon dioxide/silicon nitride bi-layer or a silicon nitride layer alone 8 is then deposited and etched so as to cover the surface between the source and drain regions. Any type of electrical insulating layer can also be used.

A germanium layer (not shown) is then deposited and used as a sacrificial layer. An SiO₂ layer or any other material compatible with the other layers present in the structure can also be used as a sacrificial layer. The thickness h of the sacrificial layer provides the final value for the height of the air gap 9 (the space under the bridge).

It is recalled that the electric field E created in the air gap is defined as the ratio between the gate voltage V_{GS} and the height of the air gap. According to an embodiment of the invention, this electric field created in the air gap has a value greater than or equal to a specific threshold value (50,000 V/cm, and preferably 100,000 V/cm, or even 200,000 V/cm). The height h of the air gap and the gate voltage V_{GS} are selected so that this condition involving the electric field E is met.

This air gap height h is low, for a given gate voltage V_{GS}, so that the electric field created in the air gap is strong and thus so that the field effect will be the predominant effect on sensitivity. In other words, this height h must be sufficiently low so that a gate voltage V_{GS} applied to the bridge creates a sufficiently strong electric field E to influence the distribution of electrical charges contained in the environment and present in the air gap. According to an embodiment of the invention, this height is less than or equal to 1 μm, and preferably less than or equal to 0.5 μm.

Thus, for an air gap height h equal to 0.5 μm, the electric field E is equal to at least 50,000 V/cm, 100,000 V/cm or 200,000 V/cm, depending on whether the gate voltage V_{GS} is equal to at least 2.5 V, 5 V or 10 V, respectively.

A highly in-situ doped polycrystalline silicon layer 4 is then deposited and etched in order to form the bridge that serves as a gate (G). Any other highly conductive material can also be used, which is compatible with the other layers present in the structure, and which has sufficient mechanical strength properties for maintaining the bridge.

A metallic layer (not shown) can then be deposited and etched to form the electrical source, drain and bridge (serving as a gate) contacts. The field-effect transistor structure 3 can also be produced without this metallic layer.

The sacrificial layer is etched (i.e., eliminated) so as to free the space (air gap) 9 situated beneath the bridge 4, either before or after depositing the metallic contacts, depending on the compatibility between the various materials used. In this way, the gaseous environment can occupy this space 9.

The first embodiment of the sensor, which was described above, is sensitive to various gases. Sensitivity to various environments has been shown. The structure is not sensitive to electrically neutral environments. The transistor characteristic is similar under vacuum, in an O₂ environment, or in an N₂ environment, for example. In all of these environments, the threshold voltage is very high. This high threshold voltage value is normal considering the usual MOS theory equations wherein the dielectric constant is 1 and the gate insulator has a thickness greater than or equal to 0.5 μm. The transistor characteristic varies in electrically charged environments.

A theoretical explanation will now be given for the effect characteristic of an embodiment of the invention (new distribution of the charges in the air gap, owing to the application of a strong electric field), as well as for its possible combination with the adsorption effect.

The context here involves the case of a sensor in which the shift in the threshold voltage of the transistor is due to:
the field effect (effect characteristic of an embodiment of this invention): a strong electric field is created in the air gap region, which causes a new distribution of the charges in the air gap; and
the adsorption effect (well-known effect) at the surface of a sensitive layer deposited on the active layer of the transistor. However, as already indicated above, it is clear that an embodiment of the invention also applies in the case where only the field effect is used (without being combined with the adsorption effect).

In this case, the threshold voltage V_{TH} of the sensor (i.e., the value of the gate voltage V_{GS} for which the drain-source current I_{DS} saturates), is written as:

$${V}_{TH} = {Φ}_{MS} + 2 {ϕ}_{F} + \frac{{Q}_{sc}}{C} - \frac{1}{{Ce}_{ox}} {\int }_{0}^{{e}_{0}} x ρ ( x ) d x \qquad ( 1 )$$

where Φ_{MS} is the difference between the work functions of the gate and the semiconductor, φ_{F} is the position of the Fermi level in relation to the middle of the forbidden band, Q_{sc} is the space charge in the semiconductor, C is the total capacity per surface unit between the bridge and the semiconductor, eₒₓ is the total thickness of the insulator (sum of the air gap height h and the thickness of the insulating layer 8, e.g., a silicon dioxide (SiO₂)/silicon nitride (Si₃N₄) bi-layer or a silicon nitride (Si₃N₄) alone), and ρ(x) is the charge in the insulator at a distance x from the bridge.

Any variation of the environment in the air gap causes a variation in the total charge in the insulator and a possible variation in its distribution. Furthermore, chemical reactions on the internal surface of the air gap (adsorption phenomenon) may occur, thereby leading to a variation in the parameter Φ_{MS}.

In the case of prior techniques, only this latter variation associated with the adsorption phenomenon is considered.

However, as an embodiment of this invention proposes, when a strong electric field is present in the air gap, the distribution of the charge in the air gap varies, which causes a variation in ρ(x). Furthermore, this strong field can influence the adsorption by pushing the charges onto the surface of the sensitive layer.

All of these effects lead to a variation in Φ_{MS} but also to the last term of the above expression (1). Consequently, the variation in the threshold voltage V_{TH} can be very large if, according to an embodiment of the invention, the effects of a strong electric field are taken into account.

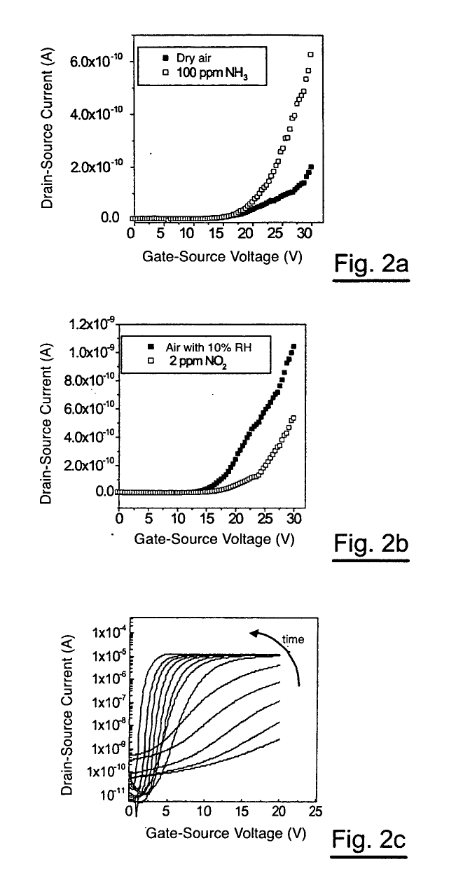

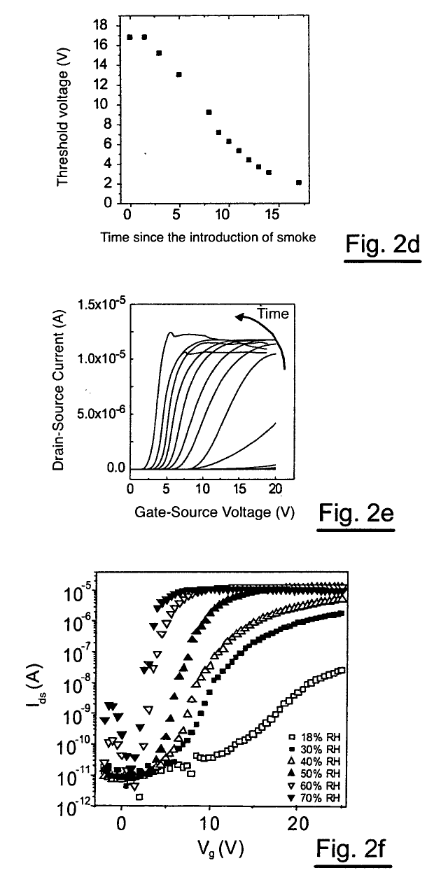

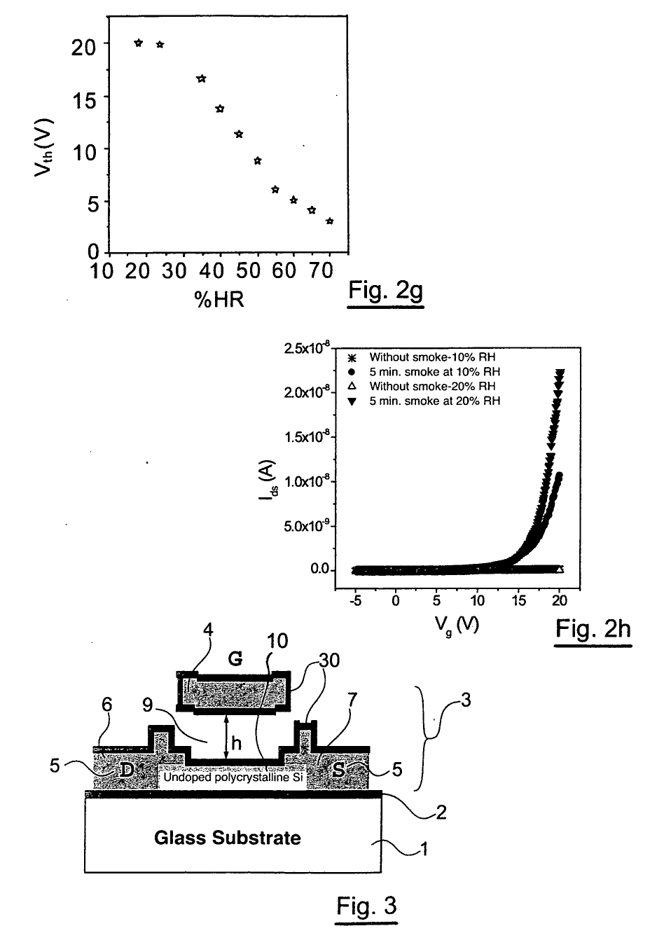

Several examples of use of this first embodiment of the sensor will now be presented in relation to FIGS. 2a to 2h. In these examples of use, the transistor is a thin-film transistor with an N-type polycrystalline silicon suspended gate. The air gap has a height of 0.5 μm. It is clear that numerous other uses can be anticipated without exceeding the scope of this invention.

FIGS. 2a and 2b show that in an NH₃ environment (FIG. 2a) or in an NO₂ environment (FIG. 2b), the structure has a significant degree of sensitivity. NO₂ and NH₃ were selected as test gases for their opposite effects on the characteristics of the transistors. FIG. 2a shows that when NH₃ is introduced, the curve I_{DS}(V_{GS}) shifts towards the weakest voltages (negative shift in the threshold voltage). FIG. 2b shows that the introduction of NO₂ has the opposite effect. Thus, a shift in the threshold voltage of 6 V is obtained with 100 ppm of NH₃ gas or 2 ppm of NO₂.

It is also seen in FIGS. 2a and 2b that, with this sensor example, the gate voltage V_{GS} must be greater than 10 V in order for detection to be possible, and thus the electric field must be greater than 200,000 V/cm (=10 V/0.5 μm).

FIGS. 2c and 2d shown that, when smoke is introduced, the threshold voltage and the slope below the threshold drop sharply, and the transfer characteristic saturates. This is particularly visible on the linear plot of FIG. 2e.

In the same way, FIGS. 2f and 2g show that, when humidity is introduced, the threshold voltage and the slope below the threshold drop sharply, and the transfer characteristic saturates. Thus, the threshold voltage varies by more than 18 V when the humidity ratio shifts from 25 to 70%.

FIG. 2h shows that the sensitivity of the structure is selective for smoke for low relative humidity ratios (e.g. when the humidity ratio is held constant and is lower than 25%).

A second particular embodiment of a sensor, which is suitable for use in a liquid environment, will no be presented in relation to FIG. 3.

This structure differs from that of FIG. 1a (first embodiment suitable for use in a gaseous environment) in that a silicon nitride layer 30 is deposited at its surface (and thus in particular at the surface of the drain 6 and source 5 regions, the active layer 10 and the suspended bridge 4). The structure thus modified can be dipped into a liquid and enable in-situ measurement in the liquid. Any other material making it possible to insulate the structure from the solution can also be used. Furthermore, the contact regions are covered with resin or any other electrical insulator.

This structure, for example, is used to measure the quantity of charges contained in a liquid. It is called, for example, an “Ion-Sensitive Thin-Film Transistor” (ISTFT).

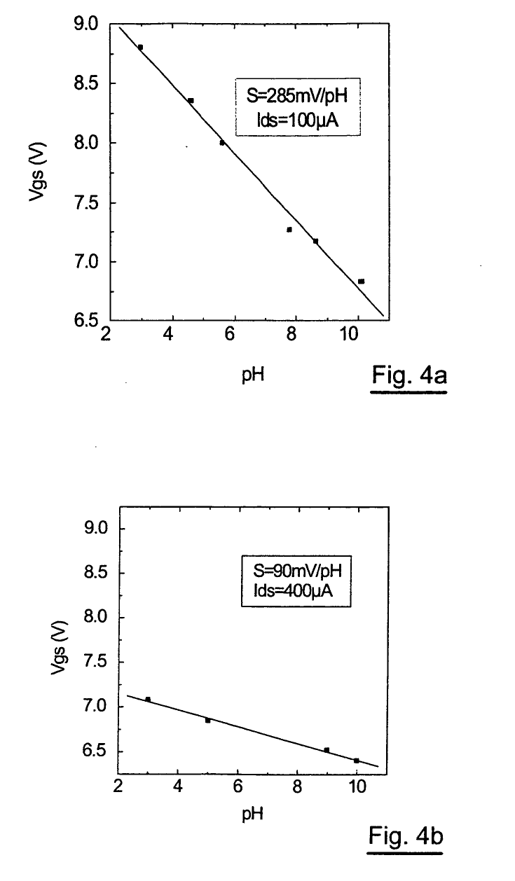

FIG. 4a shows that a pH sensitivity of 285 mV/pH is obtained with an air gap having a height equal to 0.5 μm. With an air gap height such as this, the variation in the gate voltage, between approximately 6.5V and 9V, corresponds to a variation in the electric field (in the air gap), between approximately 130,000 V/cm and 180,000 V/cm. FIG. 4b shows that this sensitivity drops to 90 mV/pH for an air gap having a height equal to 0.8 μm. With an air gap height such as this, the variation in the gate voltage, between approximately 6.25V and 7.25V, corresponds to a variation in the electric field (in the air gap), between approximately 62,500 V/cm and 72,500 V/cm. This reduction in sensitivity, in comparison with the case of FIG. 4a, shows that the field effect is predominant in obtaining high sensitivity. In other words, in a liquid, the modified structure of an embodiment of the invention provides high pH sensitivity, approximately 2 to 6 times stronger that that of the ordinary ISFET structures, this sensitivity being dependent on the thickness of the air gap.

In general, and as explained above in relation to the formula (1), the high sensitivity to electrically charged environments of the sensor according to an embodiment of the invention is explained by the strong field effect that is created (i.e., the creation of a strong electric field in the air gap, greater than or equal to 50,000 V/cm, or even 200,000 V/cm) owing, in particular, to a an air gap having a small thickness h (e.g., h<1 μm if V_{GS}>10V, or h<0.5 μm if V_{GS}>5V, in order to obtain an electric field E greater than or equal to 100,000 V/cm). When the thickness of the air gap is large and the electric field E in the air gap is less than 50,000 V/cm (the case of the prior techniques where E is much less than 1,000 V/cm), the field effect is not sufficient and the distribution of the electric charges is uniform inside the air gap. This distribution is no longer uniform when the electric field E becomes strong (greater than or equal to 50,000 V/cm), due in particular to the fact that the thickness of the air gap decreases (the case of the technique according to an embodiment of the invention). The sensitivity of the sensor according to an embodiment of the invention is heightened because of the larger accumulation of charges on one of the faces of the air gap (unlike the case of the prior technique where the distribution of charges is uniform). This accumulation becomes increasingly larger when the gate-source voltage and thus the field effect increase. The saturation of the transfer characteristic is explained by the saturation of the air gap surface when the electrical charges accumulate as a result of the field effect. This saturation appears for lower gate-source voltages (weaker field effect) when the quantity of charges contained in the environment increases. Finally, the strength of the field effect is clearly demonstrated because the pH sensitivity decreases when the thickness of the air gap increases (see above discussion of FIGS. 4a and 4b).

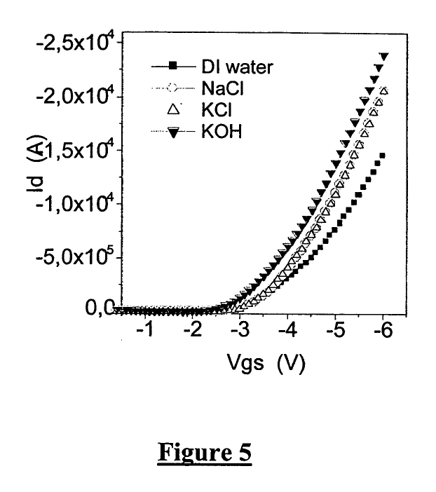

The field effect characteristic of an embodiment of the invention (new distribution of the electric charges in the air gap owing to the application of a strong electric field), as well as its possible combination with the adsorption effect, will now be illustrated by way of an example and in relation to FIG. 5.

Saline solutions of KCl and NaCl and a basic solution of KOH were prepared with exactly the same concentration.

The pH does not change when saline solutions such as KCl and NaCl are used. Consequently, when tracking the transfer characteristics of a sensor according to an embodiment of the invention, which is placed in these solutions, only the effect of the electric field on the distribution of the charges is observed.

On the other hand, in the presence of KOH, the pH changes and, as a result, not only is the effect of the new distribution of charges (under the effect of the electric field) observed, but also the adsorption effect.

FIG. 5 shows the transfer characteristics (drain-source current I_{DS}—gate voltage V_{GS}) of the same particular embodiment of a sensor, obtained after the sensor was dipped into the following liquid environments: deionised water (“DI Water”) and solutions of KOH, KCl and NaCl with the same concentration.

In the presence of KCl or NaCl with the same concentration, the same shift in the transfer characteristic is observed, in relation to the transfer characteristic obtained with the deionised water. This shift is due only to the new distribution of the electrical charges in the air gap, which results from the application of a strong electric field. The shift in the threshold voltage V_{TH} is induced by the variation in the last term of the above equation (1). The same distribution of the charges yields the same shift. With the KOH solution having the same concentration, an additional shift is observed. It is due to the pH of KOH and thus to the charges that are adsorbed at the surface of the insulating layer (referenced as 30 in FIG. 3) consisting of silicon nitride Si₃N₄ (first term of the above equation (1)). It shall be noted that, in this example, the insulating layer also serves as a sensitive layer for the adsorption process. Consequently, in the presence of KOH, the shift in the transfer characteristic is due, on the one hand, to the new distribution of charges (under the effect of the electric field) and, on the other hand, to the adsorbed charge. Thus, the two effects combine and contribute to the good pH sensitivity of this example of a sensor according to an embodiment of the invention.

An embodiment of the invention mitigates various disadvantages of the prior art.

More precisely, at least one embodiment provides a sensor comprising a field-effect transistor and having a higher degree of sensitivity than that of known sensors.

At least one embodiment provides a sensor such as this, which is capable of being used in a gaseous environment.

At least one embodiment provides a sensor such as this, which is capable of being used in a liquid environment.

At least one embodiment provides a sensor such as this, which is simple to manufacture and inexpensive.

Further, at least one embodiment provides a sensor such as this, which makes it possible to lift the constraint in the choice of material used for the sensitive layer (on which the adsorption phenomenon occurs).

Although the invention has been described above in relation to a limited number of embodiments, those skilled in the art, upon reading this description, will understand that other embodiments can be imagined without exceeding the scope of this invention. Consequently, the scope of the invention is limited only by the appended claims.

1. Sensor for detecting and/or measuring a concentration of electrical charges contained in an environment, said sensor comprising a field-effect transistor structure including a bridge which forms a gate and is suspended above an active layer situated between drain and source regions, a gate voltage having a specific value being applied to the bridge, a so-called air gap region, being included between the bridge and the active layer or an insulating layer deposited on said active layer, and having a specific height, an electric field E, defined as the ratio between the gate voltage and the air gap height, being created in the air gap, wherein the electric field created in the air gap has a value greater than or equal to a specific threshold value, which is sufficiently large for the electric field E to influence the distribution of electrical charges contained in the environment and present in the air gap, and to enable high sensor sensitivity to be obtained by an accumulation of electrical charges on the active layer, and wherein the bridge has a surface covered with an insulating material.

2. Sensor of claim 1, wherein the electric field created in the air gap has a value greater than or equal to 50,000 V/cm.

3. Sensor of claim 2, wherein the electric field created in the air gap has as value greater than or equal to 100,000 V/cm.

4. Sensor of claim 3, wherein the electric field created in the air gap has a value greater than or equal to 200,000 V/cm.

5. Sensor as claimed in claim 1, wherein the height of the air gap is less than 1 μm.

6. Sensor as claimed in claim 5, wherein the height of the air gap is less than 0.5 μm.

7. Sensor as claimed in claim 1, wherein at least a portion of the a surface of the structure, including the drain and source regions, and the active layer, is covered with the insulating material, so that the sensor can be dipped into a liquid environment.

8. A method for detecting and/or measuring a concentration of electrical charges contained in an environment, the method comprising:
providing a sensor comprising a field-effect transistor structure including a bridge, which forms a gate and is suspended above an active layer situated between drain and source regions and which has a surface covered with an insulating material, a so-called air gap region, being included between the bridge and the active layer or an insulating layer deposited on said active layer, and having a specific height;
applying a gate voltage having a specific value to the bridge, such that an electric field E, defined as the ratio between the gate voltage and the air gap height, is created in the air gap, wherein the electric field created in the air gap has a value greater than or equal to a specific threshold value, which is sufficiently large for the electric field E to influence the distribution of electrical charges contained in the environment and present in the air gap, and to enable high sensor sensitivity to be obtained by an accumulation of electrical charges on the active layer; and
measuring a change in a characteristic of the field-effect transistor due to the accumulation.

9. The method of claim 8, wherein the environment containing electrical charges belongs to the group including gaseous and liquid environments.

10. The method of claim 9, wherein the electrical charges are NH₃ molecules contained in a gaseous environment.

11. The method of claim 9, wherein the electrical charges are NO₂ molecules contained in a gaseous environment.

12. The method of claim 9, wherein the electrical charges are H⁺ ions contained in a liquid environment.

13. The method of claim 8, comprising detecting and/or measuring a humidity ratio in a gaseous environment, by detecting and/or measuring a concentration of OH⁻ ions contained in said gaseous environment with the sensor.

14. The method of claim 8, comprising detecting and/or measuring a concentration of smoke in a gaseous environment, by detecting and/or measuring electrical charges contained in said smoke and contained in said gaseous environment with the sensor.

15. The method of claim 8, comprising measuring air quality, by measuring a quantity of negative electrical charges contained in the air with the sensor.

16. The method of claim 8, comprising detecting and/or measuring a void fraction in a gaseous environment, by detecting and/or measuring electrical charges that have not been eliminated from said gaseous environment with the sensor.

17. The method of claim 8, comprising measuring the pH of a liquid environment, by measuring a concentration of H⁺ ions contained in said liquid environment with the sensor.

18. The method of claim 8, comprising detecting electrically charged biological entities contained in said environment with the sensor.

19. (canceled)
